(19) United States
(12) Patent Application Publication
(10) Pub. No.: US 2010/0101817 A1
(43) Pub. Date: Apr. 29, 2010

(54) CONNECTING BOX FOR FIELD DEVICE

(75) Inventors: Karl-Heinz RACKEBRANDT, Adelebsen (DE); Harald Grothey, Gottingen (DE)

Correspondence Address: BUCHANAN, INGERSOLL & ROONEY PC, POST OFFICE BOX 1404, ALEXANDRIA, VA, 22313-1404, US

(73) Assignee: ABB Technology AG, Zurich (CH)

(21) Appl. No.: 12/604,888

(22) Filed: Oct. 23, 2009

(30) Foreign Application Priority Data
Oct. 23, 2008 (DE) 10 2008 052 912.5

(51) Int. Cl. G01F 15/14; H01R 13/46; H05K 5/06

(52) U.S. Cl. 174/50.52; 174/59; 174/521; 73/273

(57) ABSTRACT

A connecting box is provided for a field device. To simplify installation even in the case of physically small devices, a connecting terminal of the connecting box is arranged in a cover of the connecting box so that when the cover is closed, the connecting terminal is contact-connectd to a contact strip arranged in the cover and having contacts corresponding to those of the connecting terminal.

### RELATED APPLICATION

This application claims priority under 35 U.S.C. §119 to German Patent Application No. 10 2008 052 912.5 filed in Germany on Oct. 23, 2008, the entire content of which is hereby incorporated by reference in its entirety.

### FIELD

The present disclosure relates to a connecting device for a field device for the process industry, such as a flowmeter, for example.

### BACKGROUND INFORMATION

Process devices have an external connecting interface that includes one end connected to a power supply, and another end connected to signal lines. These connecting boxes (interfaces) should be able to be handled in a practical manner for purposes such as cabling, for example.

With an increasing trend to produce compact field devices, the connecting boxes are sometimes made smaller structurally, which resultantly makes manual connection difficult.

### SUMMARY

An exemplary embodiment provides a field device having a connecting box. The exemplary connecting box comprises a cover configured to be closed and in which a connecting terminal is configured to be arranged. The connecting terminal is arranged in the cover of the connecting box so that the connecting terminal is contact-connected to a contact strip arranged in the cover and having contacts corresponding to the connecting terminal, when the cover on the connecting box is closed.

### BRIEF DESCRIPTION OF THE DRAWINGS

Additional features, refinements, improvements, and advantages of the present disclosure will be explained in more detail below with reference to exemplary embodiments illustrated in the accompanying drawing, in which:

FIG. 1 illustrates an exemplary connecting box according to at least one embodiment of the present disclosure.

### DETAILED DESCRIPTION

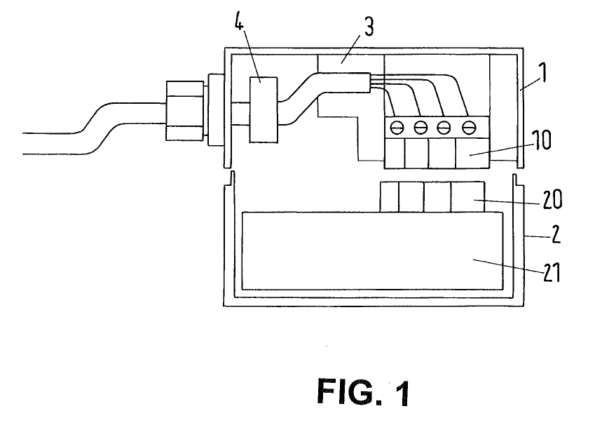

The exemplary connecting box illustrated in FIG. 1 can be utilized in and connected to any desired field device. The field device may be, for example, a flowmeter, an analysis device, a position controller of a valve, etc. Signal and/or supply lines are connected in all cases. Since any desired field device can be connected to the exemplary connecting box illustrated in FIG. 1, the field device is not illustrated. However, it is to be understood that the exemplary connecting box is fastened to the field device, such as on the outside of the field device, for example.

Therefore, an aspect of the present disclosure is based on the object of simplifying installation even in the case of physically small devices or field devices with small connecting boxes.

According to an exemplary embodiment of the present disclosure, the connecting terminal or terminal block can be arranged in the cover of the connecting box, and a contact strip whose contacts correspond to the connecting terminal or terminal block is arranged in the connecting box in such a manner that, when the cover on the connecting box is closed, the connecting terminal or terminal block is contact-connected to the contact strip.

Since field devices are becoming more and more compact, this exemplary arrangement overcomes the initially described problem of the connecting terminal which is often accessed with difficulty. When the cover is removed, the cables or signal cables can be connected to the easily accessible connecting terminal or terminal block placed there, according to an exemplary embodiment of the present disclosure. Laborious tinkering in a small connecting box when connecting the connecting line is thus overcome. Installation is thus considerably simplified.

Another exemplary embodiment provides that a strain relief device, which is intended for an inserted signal line and/or a cable shield terminal, can be arranged in the cover of the connecting box.

Another exemplary embodiment provides that, when a metal cover is used, fastening elements for the terminal or terminal block are screwed in.

Another exemplary embodiment provides that, when a plastic cover is used, fastening elements for the terminal or terminal block are concomitantly injected into the plastic.

Another exemplary embodiment provides that, in addition to the strain relief device, a cable guide can be concomitantly integrated in the cover.

Another exemplary embodiment provides that a sensor system, a measuring transducer, and/or a printed circuit board for electronic signal conditioning can be introduced into the connecting box and be directly electrically connected to the contact strip in an appropriate manner.

Another exemplary embodiment provides that the sensor system, the measuring transducer and/or the printed circuit board for electronic signal conditioning can be encapsulated in an encapsulating material.

Another exemplary embodiment provides that the connecting box, which is closed with its cover, is hermetically sealed when closed.

Another exemplary embodiment provides that the hermetic seal is waterproof or splashproof.

Another exemplary embodiment provides that the hermetic seal is pressure-resistant.

Another exemplary embodiment provides that the hermetic seal has Ex-d protection.

Another exemplary embodiment provides that the field device is an inductive or capacitive flowmeter.

According to an exemplary embodiment illustrated in FIG. 1, the connecting box 2 can be closed using a cover 1 which can be opened and closed. In this case, the connecting line is no longer inserted into the connecting box 2 to be connected but is instead inserted into the cover 1. This configuration provides an advantage in that the cover 1 is considerably more accessible and manual installatin of the connection for the individual cables in the connecting line is enabled in a much simpler manner. Furthermore, the easy accessibility also considerably shortens the installation time.

The connecting terminal 10 to which individual cables in the connecting line 3 are connected is thus placed in the cover 1. A strain relief device 4 can also be arranged inside the cover 1.

According to an exemplary embodiment, a contact strip 20 can be arranged in the connecting box 2. When the cover 1 is closed, the contact strip 20 can interact with the connecting terminal 10 in such a manner that the connecting terminal 10 mechanically establishes electrical contact with the contact strip 20 according to the plug-coupling principle. Additional electrical and/or electronic components 21 such as a sensor system, electronics, a measuring transducer, etc. can be connected to the contact strip 20 inside the connecting box 2, and thereby be accomodated in the connecting box 2. The connecting lines of the connecting terminal 10 and contact strip 20 can then be contact-connected by means of the contact which is established when the cover 1 is closed.

In this case, the mechanical connection between the cover 1 and the connecting box 2 may be designed so as to produce a pressure-resistant enclosure, such as Ex-d protection, for example. This is a requirement in many field devices.

Overall, cabling can be carried out in a considerably simpler manner in the cover 1 than in the connecting box 2.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### LIST OF REFERENCE SYMBOLS

1 Cover
2 Connecting box
3 Signal line
4 Strain relief device
10 Connecting terminal (terminal block)
20 Contact strip
21 Sensor system, electronics, measuring transducer, etc. (as examples of electrical and/or electronic components)

What is claimed is:

1. A field device having a connecting box, wherein the connecting box comprises:
a cover configured to be closed and in which a connecting terminal is configured to be arranged,
wherein the connecting terminal is arranged in the cover of the connecting box so that the connecting terminal is contact-connected to a contact strip arranged in the cover and having contacts corresponding to the connecting terminal, when the cover on the connecting box is closed.

2. The field device as claimed in claim 1, comprising a strain relief device arranged in the cover of the connecting box, the strain relief device being configured to be connected to at least one of an inserted signal line and a cable shield terminal in the cover of the connecting box.

3. The field device as claimed in claim 1, wherein the cover is constituted by metal, and the connecting box comprises fastening elements configured to be screwed in for the connecting terminal.

4. The field device as claimed in claim 1, wherein the cover is constituted by a plastic material, and the connecting box comprises fastening elements configured to be concomitantly injected into the plastic material for the connecting terminal.

5. The field device as claimed in claim 2, comprising a cable guide concomitantly integrated in the cover with the strain relief device.

6. The field device as claimed in claim 1, comprising at least one of a sensor system, a measuring transducer, and a printed circuit board for electronic signal conditioning introduced into the connecting box and directly electrically connectable to the contact strip.

7. The field device as claimed in claim 6, wherein the at least one of the sensor system, the measuring transducer, and the printed circuit board for electronic signal conditioning is/are encapsulated in an encapsulating material.

8. The field device as claimed in claim 1, wherein the connecting box is configured to be hermetically sealed when closed.

9. The field device as claimed in claim 8, wherein the hermetic seal is at least one of waterproof and splashproof.

10. The field device as claimed in claim 8, wherein the hermetic seal is a pressure-resistant enclosure according to Ex-d protection.

11. The field device as claimed in claim 1, wherein the field device is an inductive flowmeter.

12. The field device as claimed in claim 1, wherein the field device is a flowmeter.

13. The field device as claimed in claim 2, wherein the field device is a flowmeter.

14. The field device as claimed in claim 2, wherein the cover is constituted by metal, and the connecting box comprises fastening elements configured to be screwed in for the connecting terminal.

15. The field device as claimed in claim 2, wherein the cover is constituted by a plastic material, and the connecting box comprises fastening elements configured to be concomitantly injected into the plastic material for the connecting terminal.

16. The field device as claimed in claim 1, comprising a cable guide integrated in the cover.

17. The field device as claimed in claim 1, wherein the field device is a capacitive flowmeter.
